(19) United States
(12) Patent Application Publication
(10) Pub. No.: US 2019/0245343 A1
(43) Pub. Date: Aug. 8, 2019

(54) METHOD TO DETECT UTILITY DISTURBANCE AND FAULT DIRECTION

(71) Applicant: S&C Electric Company, Chicago, IL (US)

(72) Inventors: David Glenn Porter, East Troy, WI (US); Stephen E. Williams, Franklin, WI (US)

(73) Assignee: S&C Electric Company, Chicago, IL (US)

(21) Appl. No.: 16/176,180

(22) Filed: Oct. 31, 2018

Related U.S. Application Data
(60) Provisional application No. 62/625,900, filed on Feb. 2, 2018.

(51) Int. Cl. H02H 7/28; H02J 3/00; H02H 1/00; G01R 19/25; G01R 19/02; G01R 19/165

(52) U.S. Cl. CPC H02H 7/28; H02J 3/00; H02H 1/0007; G01R 19/16528; G01R 19/02; G01R 19/2506; G01R 19/2513

(57) ABSTRACT

A method for detecting a voltage disturbance in a utility having a micro-grid. The method transforms current and voltage measurements into first and second voltage values and first and second current values in a stationary reference frame, and transforms the first and second voltage values and the first and second current values to third and fourth voltage values and third and fourth current values in a rotating reference frame, where the third voltage value defines an average magnitude of the three-phase power signals. The method multiplies the third current value by the third voltage value to obtain an instantaneous power value and multiplies the fourth current value by the third voltage value to obtain an instantaneous volt-ampere reactive (VAR) value. The method opens the switch if the VAR value has a magnitude above a predetermined value and a direction indicating the fault is outside of the micro-grid in the network.

### CROSS REFERENCE TO RELATED APPLICATION

This application claims the benefit of priority from the U.S. Provisional Application No. 62/625,900, filed on Feb. 2, 2018, the disclosure of which is hereby expressly incorporated herein by reference for all purposes.

### BACKGROUND

### Field

This disclosure relates generally to a method for detecting a voltage disturbance in an electrical power distribution network for a utility so as to disconnect a critical load from the utility and connect an uninterrupted power supply (UPS) thereto or disconnect a micro-grid from the utility and rely on a micro-grid power source to provide power to the micro-grid and, more particularly, to a method for detecting a voltage disturbance in an electrical power distribution network for a utility so as to disconnect a critical load from the utility and connect a UPS thereto or disconnect a micro-grid from the utility and rely on a micro-grid power source to provide power to the micro-grid, where the method determines whether the voltage disturbance is caused by a fault in the utility outside of the critical load or micro-grid or a fault in the critical load or micro-grid and only disconnects the critical load or the micro-grid from the utility if the fault is outside of the micro-grid or critical load.

### Discussion

A power distribution utility provides three-phase electrical power on a power distribution network to deliver the power at the proper voltage for a number of loads, such as homes, businesses, manufacturing facilities, etc. The utility includes various power sources, substations, switching devices, feeder lines, lateral lines, circuit breakers, transformers, current and voltage detectors, etc. that operate to deliver the three-phase power to the loads in a controlled and stable manner.

Faults may periodically occur in the distribution network that create short circuits or near short circuits that may significantly increase the current flow to the fault location from the power source, and may cause electrical voltage disturbances throughout the network, where the voltage sags and decreases at a certain rate and to a certain level depending on the relative location of the fault and the load. Techniques are known in the art that detect the occurrence of such faults typically by detecting a high fault current, and open circuit breakers, reclosers, etc. at the appropriate location to disconnect or remove the fault from the network as quickly as possible so as to prevent damage to circuits and components. However, some of the loads in the distribution network may be critical loads where even a small and short disturbance in the voltage of the power signal provided to those loads could have significant consequences. For example, a critical load may be a factory where even a small loss of electrical power can affect machinery in the factory that can cause productivity loss, product damage, etc. Typically, critical loads require a power service that includes all three AC voltage phases that are provided by the utility.

It is known in the art to provide an uninterruptible power supply (UPS) system for these types of critical loads that includes a detector that detects a voltage disturbance on the electrical line from the utility as a result of a fault, a switch for disconnecting the critical load from the utility when a disturbance is detected, and a power supply, such as a bank of batteries, that provides power to the critical load when the switch is opened all in a quick and seamless manner so that the power supply to the load is not interrupted. U.S. Pat. No. 5,943,246, titled, Voltage Detection of Utility Service Disturbance, issued Aug. 24, 1999 to Porter, herein incorporated by reference, discloses one known technique for detecting a voltage disturbance that includes monitoring the instantaneous voltages of all three-phases from the utility, and calculating a sliding window one-half cycle RMS voltage of each phase at a very high sample rate. The RMS voltage calculations are then compared to predetermined maximum and minimum voltage values, for example, +10% or −10% of a nominal voltage, such as 120 volts, and if the RMS voltage calculation of any of the phases exceeds those voltage values, then the system opens the switch to disconnect the critical load from the utility and connects the power supply to the critical load.

It is desirable to set the maximum and minimum voltage values and the calculation sample rate so that the system switches to the power supply very quickly as the voltage sags in response to a voltage disturbance, but not so quickly where the voltage disturbance is not significant enough, and thus is not a result of a fault. In other words, it is desirable to eliminate false positives where if there is a small glitch on the utility power that is not the result of a voltage disturbance caused by a fault, the utility is not disconnected from the critical load.

Some utilities may include one or more micro-grids, where the micro-grid includes one or more power sources, such as photovoltaic cells, diesel generators, battery modules, wind farms, etc. Micro-grids are connected to the utility by a suitable disconnect switch so that the micro-grid can be removed from the utility in the event of a fault occurring in the utility, where the various sources in the micro-grid can then support the loads in the micro-grid. During normal operation, these micro-grid power sources may be reducing the amount of power that the loads in the micro-grid are drawing from the utility, or may be placing power onto the utility.

It is known in the art to employ the sliding window one-half cycle RMS voltage measurement scheme to determine voltage disturbances on the utility discussed above, and then open the disconnect switch to disconnect the micro-grid from the utility in response thereto, which works well for voltage sags caused by electrical faults in the utility outside of the micro-grid. However, if the voltage sag is caused by an electrical fault in the micro-grid, it is desirable to continue to supply the micro-grid with the utility power because the utility has better voltage support than the sources in the micro-grid. In other words, if there is a fault in the utility outside of the micro-grid, it is possible to have a current flow from the micro-grid to the utility that feeds the fault. On the other hand, faults in the utility are best isolated from the micro-grid or the UPS load, which allows the UPS or micro-grid generation to carry the load. Thus, it would be desirable to detect which direction the fault current is flowing in relation to the disconnect switch to determine whether the switch should be opened in response to detecting a voltage disturbance.

It is possible to use the magnitude of the current flow through the disconnect switch to determine the current flow direction. However, if there are generation or motor loads in the load or micro-grid when the fault occurs high magnitude currents will flow from the load or micro-grid to the utility. In the case where the load is back feeding a fault in the utility, current magnitude alone can lead to an incorrect determination of fault current direction.

### SUMMARY

The present disclosure describes a method for detecting a voltage disturbance in a utility having a micro-grid, where the method disconnects the micro-grid from the utility only if the voltage disturbance is caused by a fault in the utility outside of the micro-grid. The method includes reading instantaneous voltage and current measurements of three-phase power signals provided by the utility to the micro-grid, and detecting the voltage disturbance using the voltage measurements. The method transforms the current and voltage measurements into first and second voltage values and first and second current values in a stationary reference frame, and transforms the first and second voltage values and the first and second current values to third and fourth voltage values and third and fourth current values in a rotating reference frame, where the third voltage value defines an average magnitude of the three-phase power signals and the fourth voltage value provides an indication of whether the third voltage value is locked to a voltage of the utility, and where the fourth voltage value is corrected over time to maintain the third voltage value locked to the utility voltage. The method multiplies the third current value by the third voltage value to obtain an instantaneous power value and multiplies the fourth current value by the third voltage value to obtain an instantaneous volt-ampere reactive (VAR) value. The method opens the switch if the VAR value has a magnitude above a predetermined value and a direction indicating the fault is outside of the micro-grid in the network.

Additional features of the present disclosure will become apparent from the following description and appended claims, taken in conjunction with the accompanying drawings.

### BRIEF DESCRIPTION OF THE DRAWINGS

FIG. 1 is a simplified schematic diagram of an electrical power distribution network including a micro-grid;

FIG. 2 is a schematic block diagram showing a method for determining the direction of fault current through a disconnect switch in the network shown in FIG. 1; and

FIG. 3 is a flow chart diagram showing a process for determining whether the disconnect switch should be opened or closed based on fault current direction.

### DETAILED DESCRIPTION OF THE EMBODIMENTS

The following discussion of the embodiments of the disclosure directed to a method for detecting a voltage disturbance in a utility and the direction of fault current between a micro-grid and the utility is merely exemplary in nature, and is in no way intended to limit the disclosure or its applications or uses.

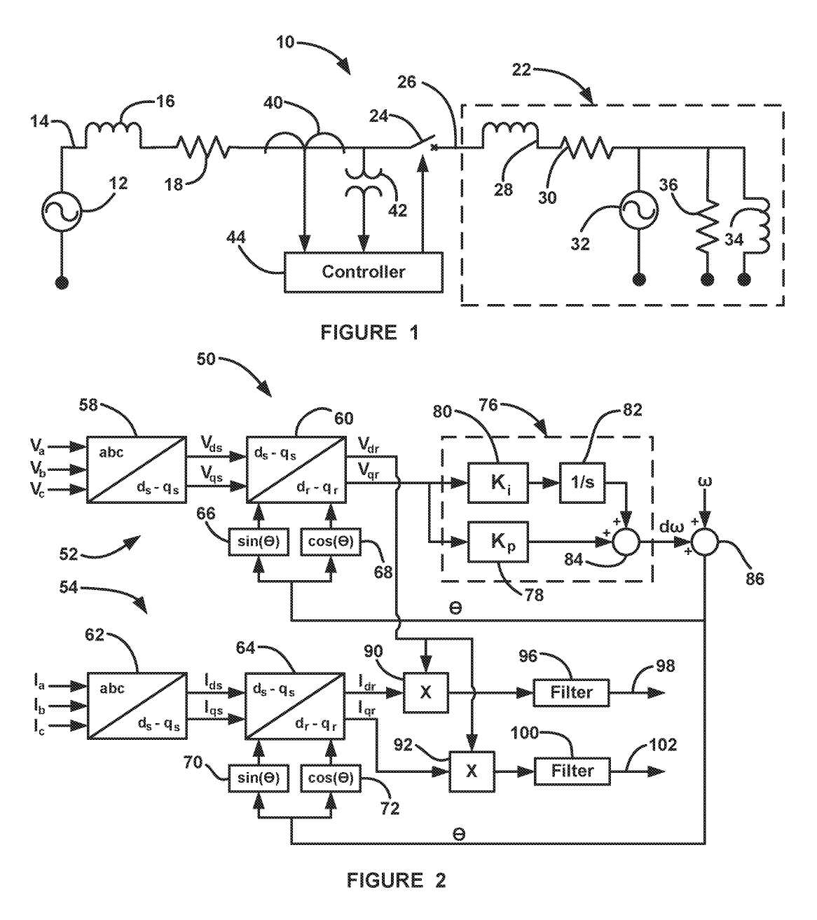

FIG. 1 is a schematic diagram of an electrical power distribution network 10, sometimes referred to herein as a utility. The network 10 is intended to represent any electrical power distribution system or network of any size and configuration that provides electrical power from any number or type of power plants (not shown) over any suitable distance on any type of transmission line (not shown) to electrical substations (not shown) to be distributed on feeder lines (not shown) to any suitable load (not shown).

The network 10 includes an AC power source 12, such as an electrical substation, that provides power on an electrical line 14 to the loads within the network 10. The line 14 is intended to represent three electrical lines each carrying one phase of a three-phase electrical service, where each phase signal on the line 14 has a line inductance represented by inductor 16 and a line resistance represented by resistor 18. The network 10 includes a UPS system or micro-grid 22 of the type referred to above having an electrical line 26 that receives power from the line 14 through a disconnect switch 24, where the line 26 also represents a line for each of the three-phase power signals and includes an inductance represented by inductor 28 and a resistance represented by resistor 30. The micro-grid 22 includes a micro-grid power source 32 intended to represent any power generation device for any application, such as photovoltaic cells, battery banks, wind farms, diesel generators, etc. The micro-grid 22 includes one or more loads that receive electrical power from the source 12 when the switch 24 is closed and/or from the micro-grid power source 32, where the load or loads are represented by an inductor 34 and a resistor 36.

Three current transformers (CTs) 40 provided in the line 14 measure the current of the three-phase AC power signals and three potential transformers (PTs) 42 provided in the line 14 measure the voltage of the three-phase power signals, and those current and voltage measurements are provided to a controller 44. As will be discussed in detail below, the controller 44 controls the position of the switch 24 so that if a voltage disturbance is detected by the controller 44 as a result of a fault in the utility, the controller 44 will open the switch 24 only if it determines that the fault is in the utility and not in the micro-grid 22. If the fault is in the micro-grid 22 it is desirable to maintain the switch 24 closed so that the various over-current protection devices and switches (not shown) in the micro-grid 22 can clear the fault without affecting all of the loads in the micro-grid 22 or the loads in the utility.

As discussed herein, the controller 44 simultaneously detects a voltage disturbance caused by a fault in the network 10 and determines whether the fault is outside or inside of the micro-grid 22 by determining the fault direction relative to the switch 24. To detect the voltage disturbance, in one non-limiting embodiment, the controller 44 employs sliding window one-half cycle RMS voltage calculations, such as discussed above in the '246 patent, to determine whether any of the three-phase voltage measurement signals Vₐ, V_{b} and V_{c} from the potential transformers 42 has sagged some predetermined maximum or minimum amount to detect the fault, although other techniques may be equally applicable. In one embodiment, the various calculations discussed herein are performed at 4800 Hz or 4800 times per second. For a 60 Hz AC signal, there would thus be 80 sample points or calculations per AC cycle. Since the sliding window is over a one-half cycle, each calculation at each sample point uses the last forty voltage measurements, where the algorithm squares each voltage measurement, adds the forty squared voltage measurements, divides the added voltage measurements by forty and takes the square root of that value to give the RMS voltage values. Alternately, the algorithm could compare added forty square values without dividing by forty.

FIG. 2 is a schematic block diagram of a system 50 showing the operation of an algorithm operating in the controller 44 that uses the voltage and current measurements from the current transformers 40 and the potential transformers 42 to determine a change in power and in volt-ampere reactive (VAR) units to determine if a fault that causes a detected voltage disturbance is outside of the micro-grid 22 in the network 10 or inside the micro-grid 22. As is known in the art, a VAR unit defines reactive power, specifically power where the current and voltage are not in phase in an AC power signal, where VARs can define either the imaginary part of the apparent power or the power flowing into a reactive load.

The system 50 includes a voltage transformation side 52 and a current transformation side 54, where the voltage transformation side 52 receives the three-phase voltage measurement signals Vₐ, V_{b} and V_{b} from the potential transformers 42 and the current transformation side 54 receives the three-phase current measurement signals Iₐ, I_{b} and I_{b} from the current transformers 40. The voltage measurement signals Vₐ, V_{b} and V_{b} are provided to a Clarke transformation block 58 that converts the three-phase voltage signals Vₐ, V_{b} and V_{b} into two-phase direct axis (d) and quadrature axis (q) voltage signals V_{ds} and V_{qs} in a stationary reference frame in a manner well understood by those skilled in the art. The two-phase voltage signals V_{ds} and V_{qs} are then provided to a Park transformation block 60 that converts the two-phase voltage signals V_{ds} and V_{qs} in the stationary reference frame to two-phase direct axis (d) and quadrature axis (q) voltage signals V_{dr} and V_{qr} in a rotating reference frame also in a manner well understood by those skilled in the art, where V_{dr} is the average magnitude of the three-phase voltage signals Vₐ, V_{b} and V_{b}. The Park transformation block 60 uses the sine of a frequency correction angle θ provided by block 66 and the cosine of the angle θ provided by block 68 to convert to the rotational reference frame.

Likewise, the current measurement signals Iₐ, I_{b} and I_{b} are provided to a Clarke transformation block 62 that converts the three-phase current signals Iₐ, I_{b} and I_{b} into two-phase direct axis (d) and quadrature axis (q) current signals I_{ds} and I_{qs} in a stationary reference frame. The two-phase current signals I_{ds} and I_{qs} are then provided to a Park transformation block 64 that converts the two-phase current signals I_{ds} and I_{qs} in the stationary reference frame to two-phase direct axis (d) and quadrature axis (q) current signals I_{dr} and I_{qr} in a rotating reference frame. Likewise, the Park transformation block 64 uses the sine of the angle θ provided by block 70 and the cosine of the angle θ provided by block 72 to convert to the rotational reference frame. The transformations performed in the blocks 60, 62, 64 and 66 can be defined by equations (1)-(8) below.

$$\begin{matrix}{V}_{ds} = \frac{2}{3} {V}_{a} - \frac{1}{3} ( {V}_{b} + {V}_{c} ) , & ( 1 ) \\ {V}_{qs} = \frac{1}{\sqrt{3}} ( {V}_{b} - {V}_{c} ) , & ( 2 ) \\ {V}_{dr} = {V}_{ds} cos ( θ ) + {V}_{qs} sin ( θ ) , & ( 3 ) \\ {V}_{qr} = {V}_{qs} cos ( θ ) - {V}_{ds} sin ( θ ) , & ( 4 ) \\ {I}_{ds} = \frac{2}{3} {I}_{a} - \frac{1}{3} ( {I}_{b} + {I}_{c} ) , & ( 5 ) \\ {I}_{qs} = \frac{1}{\sqrt{3}} ( {I}_{b} - {I}_{c} ) , & ( 6 ) \\ {I}_{dr} = {I}_{ds} cos ( θ ) + {I}_{qs} sin ( θ ) , & ( 7 ) \\ {I}_{qr} = I cos ( θ ) - {I}_{ds} sin ( θ ) . & ( 8 )\end{matrix}$$

The phase of the voltage value V_{dr} in the rotating frame needs to be synchronized or locked to the phase of the voltage on the line 14. When this occurs, the voltage value V_{dr} should be about 1 per unit (pu) and the voltage value V_{qr} should be about 0 at the nominal voltage. However, the transformation of the voltage value V_{ds} to the rotating frame may cause loss of synchronization. To maintain V_{qr} at about 0, a proportional-integral (P-I) regulator 76 operates to change the frequency correction angle θ to force the voltage value V_{qr} back to zero as it drifts therefrom. Particularly, the voltage value V_{qr} is applied to a proportional gain block 78 having a gain Kₚ and an integral gain block 80 having a gain Kᵢ, where if the voltage value V_{qr} increases or decreases from zero, proportional and integral error correction terms are generated. The integral term from the block 80 is integrated at block 82, and the proportional and integral terms are added together in a summation junction 84 to provide a frequency change value dω provided to a summation junction 86 that also receives a base frequency value ω, for example, 60 Hz, so that the output of the summation junction 86 will be a frequency correction that is converted to the frequency offset angle θ based on time that maintains the voltage value V_{qr} at zero.

If the current value I_{dr} has a magnitude I_{qr} is zero, then the power signal on the line 14 is only real power, and the current value I_{dr} will be the magnitude of the real power current, but the current value I_{qr} representing the current in the VAR direction will be zero. The voltage value V_{dr} is multiplied by the current value I_{dr} in multiplication block 90 and is multiplied by the current value I_{qr} in multiplication block 92. If the voltage and current on the line 14 are in phase, then the output of the multiplication block 90 will provide an instantaneous power value on line 98 after being filtered by a filter 96 that removes transients. If the current value I_{qr} has a magnitude, then that value multiplied by the voltage V_{qr} provides an instantaneous VAR value on line 102 after being filtered by a filter 100 that removes transients. If V_{dr} is not zero, then the full equation is P=V_{dr}*I_{d}r+V_{qr}*I_{qr} and Q=V_{dr}*I_{dr}−V_{qr}*I_{qr}.

The power and VAR values allow the controller 44 to determine the direction of the fault. The magnitude of the VAR value is analyzed to determine whether it is higher than the rating of the load, where if the current is not above this value, then fault current does not exist. By converting the three-phase voltages and currents to two phases, an instantaneous calculation of power and VARs can be provided. Therefore, depending on whether the VAR value is positive or negative identifies which direction the current is flowing through the switch 24, and thus the direction of the fault. Particularly, a positive VAR value indicates that the current is flowing through the switch 24 into the micro-grid 22 and a negative VAR value indicates that the current is flowing from the micro-grid 22 back to the utility.

The following is pseudo-code for the operations described in reference to the system 50.

LineImpedanceX = 0.06; // set the line impedance due to inductance to 6% on

a 1PU current basis

LineImpedanceR = 0.02; // set the line impedance due to resistance to 2%
LineImpedance = (LineImpedanceX\hat{ }2 + LineImpedanceR\hat{ }2)\hat{ }0.5; // complex

sum of the impedances

// Put in the overload capability at the moment. This can be a calculated
// value, or may be a fixed value.
OverLoadX = 1.0; // shown as a fixed value for simplicity
OverLoadR = 0.1; // shown as a fixed value for simplicity
// start with the voltage Clarke transform using the measured
// instant line to neutral voltages Va, Vb, and Vc
// Scaled with Vdr = 1 at 100% voltage
Vds = (2/3 * Va) − (1/3 * (Vb + Vc));
Vqs = 1/3\hat{ }.5 * (Vb − Vc);
// Now do the Park transform using Theta of the PI regulator shown in the

diagram

| Vdr = (Vds * Cos(Theta)) + (Vqs * Sin(Theta)); | |
|---|---|
| Vqr = (Vqs * Cos(Theta)) − (Vds * Sin(Theta)); | |
| // Current Clarke transform using the measured | |
| // instant line currents Ia, Ib, and Ic | |
| // scaled so an output of 1 is 1 PU current as used to calculate impedance | |
| Ids = (2/3* Ia) − (1/3 * (Ib + Ic)); | |
| Iqs = 1/3\hat{ }.5 * (Ib − Ic); | |
| // Now do the Park transform using Theta | |
| Idr = (Ids * Cos(Theta)) + (Iqs * Sin(Theta)); | |
| Iqr = (Iqs * Cos(Theta)) − (Ids * Sin(Theta)); | |
| FilteredVdr = Lowpass(Vdr); // Lowpass filter of 1 to 100 seconds typical | |
| FilteredIdr = Lowpass(Idr); // Lowpass filter with same time constant as Vdr | |
| FilteredIqr = Lowpass(Iqr); // Lowpass filter with same time constant as Vdr | |
| DeltaVdr = FilteredVdr − Vdr; // this is the change in Vdr | |
| DeltaIdr = FilteredIdr − Idr; // this is the change in Idr | |
| DeltaIqr = FilteredIqr − Iqr; // this is the change in Iqr | |
| DvFromIdr = DeltaIdr * LineImpedanceR; | // expected voltage drop from real |

power increase in load

| | |
|---|---|
| DvFromIqr = −DeltaIqr * LineImpedanceS; | // expected voltage drop from |

reactive power increase in load

| | |
|---|---|
| DvTotal = DvFromIdr + DvFromIqr; | // total expected voltage drop |

// here is the logic to determine if a fault is downstream.
// VaRms is a half cycle sliding window RMS calculation
FaultIsDownstream = False;
// if any phase is below 90% of nominal voltage and
// the Microgrid or UPS cannot supply the increased Power or VAR load
if ( ((VaRms < 0.9) ∥ (VbRms < 0.9) ∥ (VcRms < 0.9))

&& ((DeltaIdr > OverLoadR) ∥ (−DeltaIqr > OverLoadX)) )

{

if ( DvTotal > (0.5 * DeltaVdr) ) // if the voltage sag can be attributed at least

50%

// to increase in power or Vars in the load

{

| | |
|---|---|
| FaultIsDownstream = True; | // Do not open the switch between the utility |

and the load

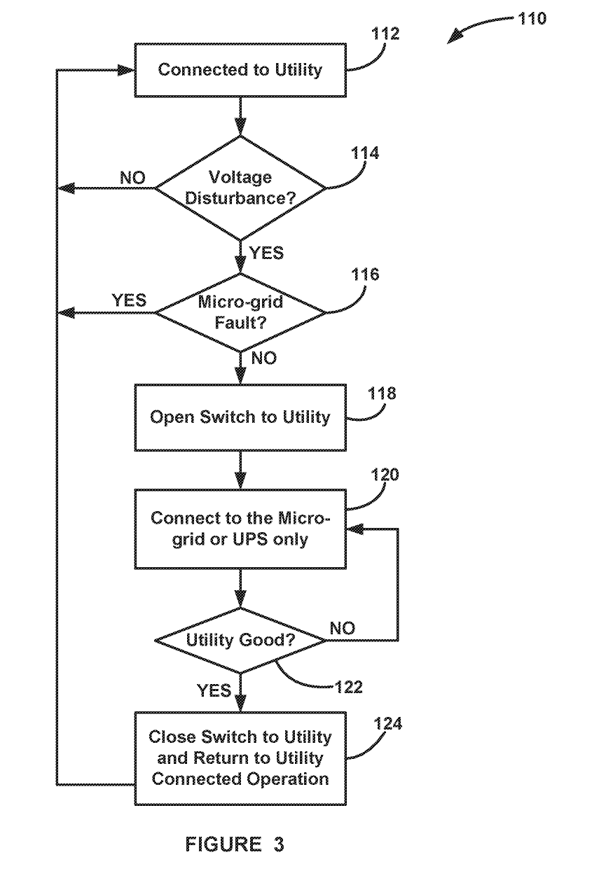

FIG. 3 is a flow chart diagram 110 showing the general operation of the algorithm discussed above for detecting a voltage disturbance and then determining whether to open the switch 24 if the voltage disturbance is caused by a fault in the utility or keep the switch 24 closed if the voltage disturbance is caused by a fault in the micro-grid 22. At box 112, the micro-grid 22 is connected to the utility and the switch 24 is closed. Decision diamond 114 determines whether there is a voltage disturbance, and if not the switch 24 remains closed. If a voltage disturbance is detected at the decision diamond 114, then the algorithm determines whether the disturbance is caused by a fault in the micro-grid 22 at decision diamond 116 in the manner discussed above with reference to FIG. 2. If the algorithm determines that the fault is in the micro-grid 22 at the decision diamond 116, then the switch 24 is maintained closed at the box 112. If the algorithm determines that the fault is in the utility and not in the micro-grid 22, then the algorithm opens the switch 24 at box 118, and operates the UPS or micro-grid source to maintain the loads in the micro-grid 22 at box 120. The algorithm then determines whether the fault has been cleared from the utility at decision diamond 122, and if not, returns to the box 120 to keep the micro-grid 22 connected to the source 32. If the fault is cleared from the utility at the decision diamond 122, then the algorithm closes the switch 24 and returns to normal operation at box 124.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

What is claimed is:

1. A method for detecting a voltage disturbance in an electrical power distribution network that includes an electrical system having one or more power sources that can be disconnected from the network by a disconnect switch provided in an electrical line, where the network provides three-phase electrical AC power signals to the electrical system, said method opening the disconnect switch in response to detecting the voltage disturbance only if the voltage disturbance is in the network outside of the electrical system, said method comprising:
reading instantaneous voltage measurements of each of the three-phase power signals on the electrical line;
reading instantaneous current measurements of each of the three-phase power signals on the electrical line;
detecting whether a fault is occurring in the distribution network by using the voltage measurements to detect a voltage disturbance on the electrical line;
transforming the voltage measurements into first and second voltage values in a stationary reference frame;
transforming the first and second voltage values in the stationary reference frame to third and fourth voltage values in a rotating reference frame, where the third voltage value defines an average magnitude of the three-phase power signals and the fourth voltage value provides an indication of whether the third voltage value is locked to a network voltage;
correcting the fourth voltage value over time to maintain the third voltage value locked to the network voltage;
transforming the current measurements into first and second current values in the stationary reference frame;
transforming the first and second current values in the stationary reference frame to third and fourth current values in a rotating reference frame;
multiplying the third current value by the third voltage value to obtain an instantaneous power value;
multiplying the fourth current value by the third voltage value to obtain an instantaneous volt-ampere reactive (VAR) value; and
opening the switch if the VAR value has a magnitude above a predetermined value and a sign indicating the voltage disturbance is outside of the electrical system in the network.

2. The method according to claim 1 wherein detecting a voltage disturbance includes calculating a sliding window root mean squared (RMS) voltage for each three-phase power signal over a first predetermined sample period using the instantaneous voltage measurements.

3. The method according to claim 1 wherein transforming the voltage measurements into first and second voltage values and transforming the current measurements into first and second current values includes employing a Clarke transformation, and wherein transforming the first and second voltage values into third and fourth voltage values and transforming the first and second current values includes into third and fourth current values includes employing a Park transformation.

4. The method according to claim 3 wherein transforming the first and second voltage values and transforming the first and second current values includes using a sine and cosine of a frequency correction angle.

5. The method according to claim 4 wherein employing the Park and Clark transformations includes using the equations:
$${V}_{ds} = \frac{2}{3} {V}_{a} - \frac{1}{3} ( {V}_{b} + {V}_{c} ) , \\ {V}_{qs} = \frac{1}{\sqrt{3}} ( {V}_{b} - {V}_{c} ) , \\ {V}_{dr} = {V}_{ds} cos ( θ ) + {V}_{qs} sin ( θ ) , \\ {V}_{qr} = {V}_{qs} cos ( θ ) - {V}_{ds} sin ( θ ) , \\ {I}_{ds} = \frac{2}{3} {I}_{a} - \frac{1}{3} ( {I}_{b} + {I}_{c} ) , \\ {I}_{qs} = \frac{1}{\sqrt{3}} ( {I}_{b} - {I}_{c} ) , \\ {I}_{dr} = {I}_{ds} cos ( θ ) + {I}_{qs} sin ( θ ) , \\ {I}_{qr} = I cos ( θ ) - {I}_{ds} sin ( θ ) ,$$
where Vₐ, V_{b} and V_{c} are the instantaneous voltage measurements of the three-phase power signals, Iₐ, I_{b} and I_{c} are the instantaneous current measurements of the three-phase power signals, V_{ds} is the first voltage value, V_{qs} is the second voltage value, V_{dr} is the third voltage value, V_{qr} is the fourth voltage value, I_{ds} is the first current value, I_{qs} is the second current value, I_{dr} is the third current value, I_{qr} is the fourth current value and θ is the frequency correction angle.

6. The method according to claim 4 wherein correcting the fourth voltage value over time includes providing the fourth voltage value to a proportional-integral (P-I) regulator that generates a correction frequency that changes a base frequency of the network, where the frequency correction angle is determined from the changed base frequency.

7. The method according to claim 1 further comprising filtering the power value and the VAR value to remove transients therefrom.

8. The method according to claim 1 wherein the electrical system is a critical load or a micro-grid.

9. The method according to claim 1 wherein opening the switch further includes looking at the current direction of the power signal.

10. A method for detecting a voltage disturbance in an electrical power distribution network that includes an electrical system having one or more power sources that can be disconnected from the network by a disconnect switch provided in an electrical line, where the network provides three-phase electrical AC power signals to the electrical system, said method opening the disconnect switch in response to detecting the voltage disturbance only if the voltage disturbance is in the network outside of the electrical system, said method comprising:
reading instantaneous voltage measurements of each of the three-phase power signals on the electrical line;
reading instantaneous current measurements of each of the three-phase power signals on the electrical line;
transforming the voltage measurements into first and second voltage values in a stationary reference frame using a Clarke transformation;
transforming the first and second voltage values in the stationary reference frame to third and fourth voltage values in a rotating reference frame using a Park transformation, where the third voltage value defines an average magnitude of the three-phase power signals and the fourth voltage value provides an indication of whether the third voltage value is locked to a network voltage;
transforming the current measurements into first and second current values in the stationary reference frame using a Clarke transformation;
transforming the first and second current values in the stationary reference frame to third and fourth current values in a rotating reference frame using a Park transformation;
multiplying the third current value by the third voltage value to obtain an instantaneous power value;
multiplying the fourth current value by the third voltage value to obtain an instantaneous volt-ampere reactive (VAR) value; and
opening the switch if the VAR value has a magnitude above a predetermined value and a sign indicating the voltage disturbance is outside of the electrical system in the network.

11. The method according to claim 10 wherein transforming the first and second voltage values and transforming the first and second current values includes using a sine and cosine of a frequency correction angle.

12. The method according to claim 11 further comprising correcting the fourth voltage value over time to maintain the third voltage value locked to the network voltage, wherein correcting the fourth voltage value over time includes providing the fourth voltage value to a proportional-integral (P-I) regulator that generates a correction frequency that changes a base frequency of the network, where the frequency correction angle is determined from the changed base frequency.

13. The method according to claim 10 wherein the electrical system is a critical load or a micro-grid.

14. A detection system for detecting a voltage disturbance in an electrical power distribution network that includes an electrical system having one or more power sources that can be disconnected from the network by a disconnect switch provided in an electrical line, where the network provides three-phase electrical AC power signals to the electrical system, said method opening the disconnect switch in response to detecting the voltage disturbance only if the voltage disturbance is in the network outside of the electrical system, said detection system comprising:
means for reading instantaneous voltage measurements of each of the three-phase power signals on the electrical line;
means for reading instantaneous current measurements of each of the three-phase power signals on the electrical line;
means for detecting whether a fault is occurring in the distribution network by using the voltage measurements to detect a voltage disturbance on the electrical line;
means for transforming the voltage measurements into first and second voltage values in a stationary reference frame;
means for transforming the first and second voltage values in the stationary reference frame to third and fourth voltage values in a rotating reference frame, where the third voltage value defines an average magnitude of the three-phase power signals and the fourth voltage value provides an indication of whether the third voltage value is locked to a network voltage;
means for correcting the fourth voltage value over time to maintain the third voltage value locked to the network voltage;
means for transforming the current measurements into first and second current values in the stationary reference frame;
means for transforming the first and second current values in the stationary reference frame to third and fourth current values in a rotating reference frame;
means for multiplying the third current value by the third voltage value to obtain an instantaneous power value;
means for multiplying the fourth current value by the third voltage value to obtain an instantaneous volt-ampere reactive (VAR) value; and
means for opening the switch if the VAR value has a magnitude above a predetermined value and a sign indicating the voltage disturbance is outside of the electrical system in the network.

15. The detection system according to claim 14 wherein the means for detecting a voltage disturbance calculates a sliding window root mean squared (RMS) voltage for each three-phase power signal over a first predetermined sample period using the instantaneous voltage measurements.

16. The detection system according to claim 14 wherein the means for transforming the voltage measurements into first and second voltage values and the means for transforming the current measurements into first and second current values employ a Clarke transformation, and wherein the means for transforming the first and second voltage values into third and fourth voltage values and the means for transforming the first and second current values includes into third and fourth current values employ a Park transformation.

17. The detection system according to claim 14 wherein the means for transforming the first and second voltage values and the means for transforming the first and second current values use a sine and cosine of a frequency correction angle.

18. The detection system according to claim 17 wherein the means for correcting the fourth voltage value over time provides the fourth voltage value to a proportional-integral (P-I) regulator that generates a correction frequency that changes a base frequency of the network, where the frequency correction angle is determined from the changed base frequency.

19. The detection system according to claim 14 wherein the electrical system is a critical load or a micro-grid.
